(19) United States
(12) Patent Application Publication
(10) Pub. No.: US 2026/0332118 A1
(43) Pub. Date: Oct. 22, 2026

(54) FILM, LAMINATE, BAND-PASS FILTER, AND COMMUNICATION TERMINAL

(71) Applicant: FUJIFILM Corporation, Tokyo (JP)

(72) Inventors: Makoto UCHIMURA, Kanagawa (JP); Hideki YASUDA, Kanagawa (JP); Yasuyuki SASADA, Kanagawa (JP); Shohei YAMAZAKI, Kanagawa (JP); Masaki KOHAMA, Kanagawa (JP)

(73) Assignee: FUJIFILM Corporation, Tokyo (JP)

(21) Appl. No.: 19/565,434

(22) Filed: Mar. 12, 2026

Related U.S. Application Data
(63) Continuation of application No. PCT/JP2024/033104, filed on Sep. 17, 2024.

(30) Foreign Application Priority Data
Sep. 15, 2023 (JP) 2023-150290

(51) Int. Cl. H03H 1/00

(52) U.S. Cl. CPC H03H 1/0007; H03H 2001/0085

(57) ABSTRACT

Provided are a film containing an inorganic filler and a resin, in which a thickness d satisfies the following expression (A), and a relative permittivity is 10 or more and a dielectric loss tangent is 0.020 or less; and applications thereof. The expression (A) is “λ(2×√ε)−λ/50≤d≤λ(2×√ε)+λ/50”.

### CROSS-REFERENCE TO RELATED APPLICATIONS

This application is a continuation application of International Application No. PCT/JP2024/033104, filed Sep. 17, 2024, the disclosure of which is incorporated herein by reference in its entirety. Further, this application claims priority from Japanese Patent Application No. 2023-150290, filed Sep. 15, 2023, the disclosure of which is incorporated herein by reference in its entirety.

### BACKGROUND OF THE INVENTION

### 1. Field of the Invention

The present disclosure relates to a film, a laminate, a band-pass filter, and a communication terminal.

### 2. Description of the Related Art

In communication equipment such as a mobile phone, a band-pass filter which transmits only a specific frequency and does not transmit other frequencies is provided in order to suppress interference of radio waves to other equipment and interference of radio waves from other equipment.

For example, JP2008-280464A discloses a filter for microwaves, including a high-permittivity resin substrate, a conductor layer of a predetermined pattern fixed to a surface of the high-permittivity resin substrate, and a ground conductor layer provided at a predetermined distance from the conductor pattern across the high-permittivity resin substrate.

JP2011-1400A discloses a high-permittivity resin composition containing a mixed resin (A) in which a thermosetting polyphenylene ether having a styrene-modified terminal and having a number-average molecular weight of 500 to 3,000 and a styrene-based elastomer are blended such that a mixing ratio of the thermosetting polyphenylene ether and the styrene-based elastomer is 60:40 to 80:20 in terms of mass ratio, and a high-permittivity inorganic insulating filler having an average particle diameter D50 of 0.7 μm or more and a maximum particle diameter of 10 μm or less is blended such that a content of the high-permittivity inorganic insulating filler is 250 to 900 parts by mass with respect to 100 parts by mass of the mixed resin (A), in which a permittivity at a measurement frequency of 1 GHz at room temperature is 10 or more and a dielectric loss tangent is less than 0.01.

### SUMMARY OF THE INVENTION

As a communication frequency is increased, a propagation loss of radio waves increases, and thus received radio waves are weakened. Therefore, it is required to suppress a loss in a transmission band in a case where a specific frequency is transmitted through the band-pass filter.

An object to be achieved by one embodiment of the present disclosure is to provide a film and a laminate, which can suppress a loss in a transmission band in a case where a specific frequency is transmitted through a band-pass filter.

Another object to be achieved by one embodiment of the present disclosure is to provide a band-pass filter and a communication terminal, using the film or the laminate.

Specific methods for achieving the object are as follows.

<1>

A film comprising:
an inorganic filler; and
a resin,
in which a thickness d satisfies the following expression (A), and
a relative permittivity is 10 or more and a dielectric loss tangent is 0.020 or less,

λ/(2×√249)−λ/50≤d≤λ(2×√ε)+λ/50 Expression (A),
in the expression (A), d represents a thickness in units of mm, λ represents a central wavelength of transmission which is expressed as 100c/f in units of mm, c represents a propagation speed of an electromagnetic wave in units of m/s, f represents a center frequency of transmission in units of GHz, and ε represents a relative permittivity.
   <2>

The film according to <1>,
in which the inorganic filler has a relative permittivity of 6 to 20,000.
   <3>

The film according to <1> or <2>,
in which the inorganic filler includes at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.
   <4>

The film according to any one of <1> to <3>,
in which the inorganic filler has an average particle diameter of 0.01 μm to 10 μm.
   <5>

The film according to any one of <1> to <4>,
in which a content of the inorganic filler is 1% by volume to 90% by volume with respect to a total amount of the film.
   <6>

The film according to any one of <1> to <5>,
in which the resin includes at least one selected from the group consisting of a thermoplastic resin, a thermoplastic elastomer, a semicured product of a thermosetting resin, a cured product of a thermosetting resin, a semicured product of a thermosetting elastomer, and a cured product of a thermosetting elastomer.
   <7>

The film according to any one of <1> to <6>,
in which the thickness is 0.1 mm to 8 mm.
   <8>

A laminate comprising:
a resin substrate having a dielectric loss tangent of 0.020 or less; and
a metamaterial layer including a conductor pattern formed of at least one selected from the group consisting of a conductive material and a material which changes from an insulator to a conductor, the conductor pattern being disposed on at least one surface of the resin substrate.
   <9>

The laminate according to <8>,
in which the resin substrate has a relative permittivity of 10 or more.
   <10>

The laminate according to <8> or <9>,
in which the resin substrate contains an inorganic filler and a resin.
   <11>

The laminate according to <10>,
in which the inorganic filler has a relative permittivity of 6 to 20,000.
   <12>

The laminate according to <10> or <11>,
in which the inorganic filler includes at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.
   <13>

The laminate according to any one of <10> to <12>,
in which the inorganic filler has an average particle diameter of 0.01 μm to 10 μm.
   <14>

The laminate according to any one of <10> to <13>,
in which a content of the inorganic filler is 1% by volume to 90% by volume with respect to a total amount of the resin substrate.
   <15>

The laminate according to any one of <10> to <14>,
in which the resin includes at least one selected from the group consisting of a thermoplastic resin, a thermoplastic elastomer, a semicured product of a thermosetting resin, a cured product of a thermosetting resin, a semicured product of a thermosetting elastomer, and a cured product of a thermosetting elastomer.
   <16>

The laminate according to any one of <8> to <15>,
in which the conductor pattern has an area resistivity of 1Ω/□ or less.
   <17>

A band-pass filter comprising:
the film according to any one of <1> to <7> or the laminate according to any one of <8> to <16>.
   <18>

The band-pass filter according to <17>,
in which a center frequency of a transmission band is 6 GHz to 24 GHz.
   <19>

The band-pass filter according to <17> or <18>,
in which an insertion loss at a center frequency of a transmission band 5 GHz is 5 dB or more.
   <20>

The band-pass filter according to any one of <17> to <19>,
in which the band-pass filter is used by being attached to an outside of an antenna.
   <21>

A communication terminal comprising:
a communication circuit;
an antenna; and
the band-pass filter according to any one of <17> to <20>, which is disposed on an outside of the antenna.

According to one embodiment of the present disclosure, there are provided a film and a laminate, which can suppress a loss in a transmission band in a case where a specific frequency is transmitted through a band-pass filter.

In addition, according to one embodiment of the present disclosure, there are provided a band-pass filter and a communication terminal, using the film or the laminate.

### BRIEF DESCRIPTION OF THE DRAWINGS

FIG. 1 is a diagram showing one aspect of a conductor pattern of a metamaterial layer in the present disclosure.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

In addition, the term “step” in the present specification indicates not only an independent step but also a step which cannot be clearly distinguished from other steps as long as the intended purpose of the step is achieved.

Furthermore, in the present disclosure, a combination of two or more preferred aspects is a more preferred aspect.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

An average particle diameter (for example, D50) of the inorganic filler in the present disclosure is measured using a laser diffraction/scattering-type particle size distribution analyzer. As the laser diffraction/scattering-type particle size distribution analyzer, for example, LA-950V2 manufactured by Horiba, Ltd. is used.

### [Film]

The film according to the present disclosure contains an inorganic filler and a resin, in which a thickness d satisfies the following expression (A), and a relative permittivity is 10 or more and a dielectric loss tangent is 0.020 or less.

λ/(2×√ε)−λ/50≤d≤λ/(2×√ϑ)+λ/50 Expression (A)

In the expression (A), d represents a thickness in units of mm, λ represents a central wavelength of transmission which is expressed as 100c/f in units of mm, c represents a propagation speed of an electromagnetic wave in units of m/s, f represents a center frequency of transmission in units of GHz, and ε represents a relative permittivity.

In the film according to the present disclosure, since the thickness d satisfies the expression (A), a loss in a transmission band in a case where a specific frequency is transmitted through a band-pass filter can be suppressed.

By designing the thickness d to satisfy the expression (A), electromagnetic waves reflected on a front surface and electromagnetic waves reflected on a back surface interfere with each other, so that a transmittance of electromagnetic waves corresponding to a central wavelength λ can be increased. In a case where the thickness d is ±λ/50 or less, the transmittance of the central wavelength λ is substantially unchanged.

On the other hand, JP2008-280464A and JP2011-1400A do not disclose a relationship between the central wavelength of transmission and the relative permittivity, and the thickness.

### (Inorganic Filler)

Examples of the inorganic filler contained in the film include barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.

It is preferable that the inorganic filler includes at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide. Among these, it is more preferable that the inorganic filler is barium titanate or titanium oxide.

The inorganic filler preferably has a relative permittivity of 6 to 20,000 and more preferably has a relative permittivity of 20 to 20,000, at 25 °C and a frequency of 10 GHz.

From the viewpoint of achieving both alignment state and dielectric characteristics, an average particle diameter of the inorganic filler is preferably 0.01 μm to 10 μm, more preferably 0.02 μm to 2 μm, and particularly preferably 0.03 μm to 5 μm.

The average particle diameter is measured using a laser diffraction/scattering-type particle size distribution analyzer. As the laser diffraction/scattering-type particle size distribution analyzer, for example, LA-950V2 manufactured by Horiba, Ltd. is used.

A shape of the inorganic filler is not particularly limited, and may be amorphous or spherical. From the viewpoint of increasing a content of the inorganic filler in the film to improve the relative permittivity of the film, the shape of the inorganic filler is preferably spherical.

The inorganic filler contained in the film may be only one kind or two or more kinds.

From the viewpoint of achieving both dielectric characteristics and mechanical properties, a content of the inorganic filler is preferably 1% by volume to 90% by volume, more preferably 20% by volume to 90% by volume, still more preferably 30% by volume to 85% by volume, and particularly preferably 40% by volume to 80% by volume with respect to the total amount of the film.

In addition, the inorganic filler may be subjected to a surface treatment with an inorganic substance or an organic substance. Examples of a method for the surface treatment include (1) modification by coating, (2) topochemical modification, (3) modification by a mechanochemical reaction, (4) modification by encapsulation, and (5) irradiation with radiation.

### (Resin)

Examples of the resin contained in the film include a thermoplastic resin, a thermoplastic elastomer, a semicured product or a cured product of a thermosetting resin, and a semicured product or a cured product of a thermosetting elastomer.

It is preferable that the resin includes at least one selected from the group consisting of a thermoplastic resin, a thermoplastic elastomer, a semicured product of a thermosetting resin, a cured product of a thermosetting resin, a semicured product of a thermosetting elastomer, and a cured product of a thermosetting elastomer.

Examples of the thermoplastic resin include a polyester resin (including liquid crystal polymers), a cyanate resin, a coumarone resin, a polyurethane resin, a (meth)acrylic resin, a polystyrene resin, a fluororesin, a polyimide resin, a fluorinated polyimide resin, a polyamide resin, a polyamideimide resin, a polyetherimide resin, a cellulose acylate resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

Examples of the thermoplastic elastomer include an elastomer containing a structural unit derived from styrene (polystyrene-based elastomer), a polyester-based elastomer, a polyolefin-based elastomer, a polyurethane-based elastomer, a polyamide-based elastomer, a polyacryl-based elastomer, a silicone-based elastomer, and a polyimide-based elastomer. The thermoplastic elastomer may be a hydrogenated product.

Examples of the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrogenated products thereof.

Examples of the thermosetting resin include epoxy resins which are monomers, oligomers, or polymers having two or more epoxy groups in one molecule, and molecular weight and molecular structure thereof are not particularly limited.

Examples of the epoxy resin include a biphenyl-type epoxy resin; a bisphenol-type epoxy resin such as a bisphenol A-type epoxy resin, a bisphenol F-type epoxy resin, and a tetramethylbisphenol F-type epoxy resin; a stilbene-type epoxy resin; a novolac-type epoxy resin such as a phenol novolac-type epoxy resin and a cresol novolac-type epoxy resin; a polyfunctional epoxy resin such as a trishydroxyphenylmethane-type epoxy resin and an alkyl-modified trishydroxyphenylmethane-type epoxy resin; an aralkyl-type epoxy resin such as a phenol aralkyl-type epoxy resin having a phenylene skeleton and a phenol aralkyl-type epoxy resin having a biphenylene skeleton; a naphthol-type epoxy resin such as a dihydroxynaphthalene-type epoxy resin and an epoxy resin obtained by glycidyl etherifying a dimer of dihydroxynaphthalene; a triazine ring-containing epoxy resin such as triglycidyl isocyanurate and monoallyl diglycidyl isocyanurate; and a bridged cyclic hydrocarbon compound-modified phenol-type epoxy resin such as a dicyclopentadiene-modified phenol-type epoxy resin.

From the viewpoint of improving balance between moisture resistance reliability and moldability, the epoxy resin is preferably at least one selected from the group consisting of a bisphenol-type epoxy resin, a novolac-type epoxy resin, a biphenyl-type epoxy resin, a phenol aralkyl-type epoxy resin, and a triphenylmethane-type epoxy resin; and more preferably at least one selected from the group consisting of a biphenyl-type epoxy resin and a phenol aralkyl-type epoxy resin.

It is preferable that the semicured product of the thermosetting resin and the cured product of the thermosetting resin are obtained by semicuring and curing the above-described thermosetting resin, respectively.

Examples of a curing agent for curing the epoxy resin include amines including linear aliphatic diamines having 2 to 20 carbon atoms, such as ethylenediamine, trimethylenediamine, tetramethylenediamine, and hexamethylenediamine, and metaphenylenediamine, paraphenylenediamine, paraxylene diamine, 4,4′-diaminodiphenylmethane, 4,4′-diaminodiphenylpropane, 4,4′-diaminodiphenyl ether, 4,4′-diaminodiphenyl sulfone, 4,4′-diaminodicyclohexane, bis(4-aminophenyl)phenylmethane, 1,5-diaminonaphthalene, metaxylene diamine, 1,1-bis(4-aminophenyl)cyclohexane, and dicyanodiamide; resol-type phenol resins such as an aniline-modified resol resin and a dimethyl ether resol resin; novolac-type phenol resins such as a phenol novolac resin, a cresol novolac resin, a tert-butylphenol novolac resin, and a nonylphenol novolac resin; polyfunctional phenol resins such as a triphenylmethane-type phenol resin; phenol aralkyl resins such as a phenol aralkyl resin containing a phenylene skeleton and a phenol aralkyl resin containing a biphenylene skeleton; phenol resins having a fused polycyclic structure such as a naphthalene skeleton or an anthracene skeleton; polyoxystyrenes such as poly(paraoxystyrene); acid anhydrides including an alicyclic acid anhydride such as hexahydrophthalic anhydride (HHPA) and methyltetrahydrophthalic anhydride (MTHPA), and an aromatic acid anhydride such as trimellitic acid anhydride (TMA), pyromellitic acid anhydride (PMDA), and benzophenonetetracarboxylic acid dianhydride (BTDA); polymercaptan compounds such as polysulfide, thioester, and thioether; isocyanate compounds such as an isocyanate prepolymer and a blocked isocyanate; and organic acids such as a carboxylic-acid-containing polyester resin.

The curing agent may be used alone or in combination of two or more thereof.

An addition amount of the curing agent is not particularly limited, but is, for example, preferably 0.1% by mass to 20% by mass, more preferably 0.5% by mass to 10% by mass, and still more preferably 1% by mass to 5% by mass with respect to the total content of the resin and the curing agent.

Examples of the thermosetting elastomer include silicone rubber, fluororubber, and urethane rubber.

Examples of the silicone rubber include vinyl group-containing organopolysiloxane.

It is preferable that the semicured product of the thermosetting elastomer and the cured product of the thermosetting elastomer are obtained by semicuring and curing the above-described thermosetting elastomer, respectively.

Among these, the resin preferably includes a liquid crystal polymer.

The type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450 °C or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

The liquid crystal polymer may be a polymer in which a bond derived from an isocyanate, such as an imide bond, a carbodiimide bond, and an isocyanurate bond, is further introduced into the aromatic polyester or the aromatic polyester amide.

In addition, it is preferable that the liquid crystal polymer is a wholly aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

A melting point of the liquid crystal polymer is preferably higher than 260 °C, more preferably higher than 260 °C and 350 °C or lower, and still more preferably higher than 260 °C and 330 °C or lower.

In the present disclosure, the melting point is measured using a differential scanning calorimetry device. For example, the measurement is performed using product name “DSC-60A Plus” (manufactured by Shimadzu Corporation). A temperature increase rate in the measurement is set to 10 °C/min.

A weight-average molecular weight of the liquid crystal polymer is preferably 1,000,000 or less, more preferably 3,000 to 300,000, still more preferably 5,000 to 100,000, and particularly preferably 5,000 to 30,000.

The liquid crystal polymer preferably includes aromatic polyester amide from the viewpoint of further decreasing the dielectric loss tangent. The aromatic polyester amide is resin having at least one aromatic ring and having an ester bond and an amide bond. Among these, from the viewpoint of heat resistance, the aromatic polyester amide is preferably a wholly aromatic polyester amide.

The aromatic polyester amide is preferably a crystalline polymer. It is preferable that the film contains a crystalline aromatic polyester amide. In a case where the aromatic polyester amide is crystalline, the dielectric loss tangent is further decreased.

The crystalline polymer refers to a polymer having a clear endothermic peak, rather than a stepwise change in endothermic amount, in differential scanning calorimetry (DSC). Specifically, for example, it means that a half-width of an endothermic peak in measuring at a temperature increase rate 10 °C/min is within 10 °C. A polymer in which the half-width exceeds 10 °C and a polymer in which the clear endothermic peak is not recognized are distinguished as an amorphous polymer from a crystalline polymer.

The aromatic polyester amide preferably contains a structural unit represented by Formula 1, a structural unit represented by Formula 2, and a structural unit represented by Formula 3.

—O—Ar¹—CO— Formula 1

—CO—Ar²—CO— Formula 2

—NH—Ar³—O— Formula 3

In Formula 1 to Formula 3, Ar¹, Ar², and Ar³ each independently represent a phenylene group, a naphthylene group, or a biphenylylene group.

Hereinafter, the structural unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a structural unit derived from p-hydroxybenzoic acid.

In a case where Ar¹ is a 2,6-naphthylene group, the unit 1 is, for example, a structural unit derived from 6-hydroxy-2-naphthoic acid.

In a case where Ar¹ is a 4,4′-biphenylylene group, the unit 1 is, for example, a structural unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a structural unit derived from terephthalic acid.

In a case where Ar² is an m-phenylene group, the unit 2 is, for example, a structural unit derived from isophthalic acid.

In a case where Ar² is a 2,6-naphthylene group, the unit 2 is, for example, a structural unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a structural unit derived from p-aminophenol.

In a case where Ar³ is a 4,4′-biphenylylene group, the unit 3 is, for example, a structural unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35 mol % or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the structural units is a value obtained by totaling a substance amount (mol) of each structural unit. The substance amount of each structural unit is calculated by dividing a mass of each structural unit constituting the aromatic polyester amide by a formula weight of each structural unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

The aromatic polyester amide may contain two kinds or more of the unit 1 to the unit 3 each independently. In addition, the aromatic polyester amide may have other structural units other than the unit 1 to the unit 3. A content of other structural units is preferably 10% by mole or less and more preferably 5% by mole or less with respect to the total content of all structural units.

The aromatic polyester amide is preferably produced by subjecting a source monomer corresponding to the structural unit constituting the aromatic polyester amide to melt polymerization.

A weight-average molecular weight of the aromatic polyester amide is preferably 1,000,000 or less, more preferably 3,000 to 300,000, still more preferably 5,000 to 100,000, and particularly preferably 5,000 to 30,000.

The resin contained in the film may be only one kind or two or more kinds.

From the viewpoint of achieving both dielectric characteristics and mechanical properties, a content of the resin is preferably 10% by volume to 80% by volume, more preferably 15% by volume to 70% by volume, and still more preferably 20% by volume to 60% by volume.

The film may contain an additive in addition to the inorganic filler and the resin.

Examples of the additive include a polymerization initiator, a dispersant, a surfactant, a crosslinking agent, and an antioxidant.

### (Physical Properties)

### -Dielectric Loss Tangent-

The dielectric loss tangent of the film is 0.020 or less, preferably 0.00050 to 0.020 and more preferably 0.00010 to 0.010.

### -Relative Permittivity-

The relative permittivity of the film is 10 or more, preferably 10 to 1,000 and more preferably 30 to 100.

In the present disclosure, the relative permittivity and the dielectric loss tangent are measured by the following method.

The relative permittivity and the dielectric loss tangent are measured by a resonant perturbation method at a frequency of 10 GHz. A 10 GHz cavity resonator (“CP531” manufactured by Kanto Electronic Application & Development Inc.) is connected to a network analyzer (“E8363B” manufactured by Agilent Technology Company), the film is inserted into the cavity resonator, and the measurement is performed from the change in resonance frequency before and after the insertion for 96 hours in an environment of a temperature of 25 °C and a humidity of 60% RH.

### -Thickness-

The thickness d satisfies the following expression (A).

The film has a relative permittivity of 10 or more, and has a dielectric loss tangent of 0.020 or less.

λ/(2×√ε)−λ/50≤d≤λ/(2×√ε)+λ/50 Expression (A)

[λ]
λ represents a central wavelength of transmission which is expressed as 100c/f in units of mm.
c represents a propagation speed of an electromagnetic wave in units of m/s.
f represents a center frequency of transmission in units of GHz.

The central wavelength of transmission means a central wavelength of radio waves transmitted through the film.

In a case where the propagation speed of an electromagnetic wave is approximately 3×10⁸ m/s and the center frequency of transmission is 10 GHz, the central wavelength of transmission is approximately 30 mm.

The central wavelength of transmission is measured by the following method.

A receiving horn antenna is connected to a Port 1 of a network analyzer (“E8363B” manufactured by Agilent Technology Company), and a transmitting horn antenna is connected to a Port 2. The receiving horn antenna and the transmitting horn antenna are disposed such that the receiving horn antenna and the transmitting horn antenna face each other.

A steel sheet is bonded to a radio wave absorber having an opening portion to produce a sample holding member. Both ends of a measurement sample are inserted into opening portions of the two sample holding members.

The measurement sample held by the sample holding member is disposed between the receiving horn antenna and the transmitting horn antenna such that radio waves can be transmitted through the measurement sample.

The radio waves are transmitted and received, and an S parameter S21 is measured. An attenuation amount (insertion loss) of the radio waves in a case where the measurement sample is installed is measured using the transmittance in a case where the measurement sample is not installed as a reference. The insertion loss is plotted with respect to the frequency, and center values of frequencies f1 and f2 at which the loss amount corresponds to 50%=approximately 3 dB are defined as the center frequency of transmission.

The center frequency of transmission is set to, for example, 6 GHz to 24 GHz.

[d]

The thickness of the film satisfies the above expression (A), and is, for example, 0.1 mm to 8 mm.

The thickness of the film is measured at five arbitrary sites using an adhesive film thickness meter, for example, an electronic micrometer (product name, “KG3001A”, manufactured by Anritsu Corporation), and an average value of the measured values is defined as the thickness of the film.

### <Manufacturing Method of Film>

A manufacturing method of the film is not particularly limited, and a known method can be referred to.

Suitable examples of the film forming method include a co-casting method, a multi-layer coating method, and a co-extrusion method, and the film can also be produced using a dispenser or the like.

In a case where a multilayer structure is produced by a co-casting method or a multi-layer coating method, it is preferable to perform the co-casting method or the multi-layer coating method using a solution or the like, which is obtained by dissolving or dispersing each component of each layer in a solvent.

It is preferable that the manufacturing method of the film includes a step of performing dispersion treatment with a beads mill to prepare a solution, and a step of forming a film using the solution.

By performing the dispersion treatment with the beads mill, an effect of reducing and homogenizing aggregates of particles can be obtained.

It is preferable that a bead diameter of beads used in the beads mill is larger than an average particle diameter of the particles used for preparing the solution. The bead diameter is, for example, 0.1 mm to 5 mm.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and 7-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as 7-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease of removal, a solvent containing, as a main component, a compound having a boiling point of 220 °C or lower at 1 atm is preferable, and a proportion of the compound having a boiling point of 220 °C or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220 °C or lower at 1 atm as the above-described aprotic compound.

In addition, in a case where the manufacturing method of the film is the co-casting method, the multilayer coating method, the co-extrusion method, or the like described above, a support may be used in the manufacturing method.

Examples of the support include a metal drum, a metal band, a glass plate, a resin film, and a metal foil. Among these, the support is preferably a metal drum, a metal band, or a resin film.

In addition, the support may have a surface treatment layer formed on the surface so that the support can be easily peeled off. Hard chrome plating, a fluororesin, or the like can be used as the surface treatment layer.

An average thickness of the support is not particularly limited, but is preferably 25 μm to 75 μm and more preferably 50 μm to 75 μm.

In addition, a method for removing at least a part of the solvent from a cast or applied film-like composition (a coating film) is not particularly limited, and a known drying method can be used.

### [Laminate]

The laminate according to the present disclosure includes a resin substrate having a dielectric loss tangent of 0.020 or less, and a metamaterial layer including a conductor pattern formed of at least one selected from the group consisting of a conductive material and a material which changes from an insulator to a conductor, the conductor pattern being disposed on at least one surface of the resin substrate.

The metamaterial layer can propagate (transmit) a specific wavelength by including a specific conductor pattern. The laminate is also referred to as a laminated plate.

### <Resin Substrate>

A preferred aspect of the resin substrate in the laminate is the same as the preferred aspect of the film described above.

The resin substrate preferably contains an inorganic filler and a resin.

Preferred aspects of the inorganic filler and the resin, which may be contained in the resin substrate, are the same as the preferred aspects of the inorganic filler and the resin contained in the film.

The resin substrate may contain an additive in addition to the inorganic filler and the resin. Examples of the additive include a polymerization initiator, a dispersant, a surfactant, a crosslinking agent, and an antioxidant.

### (Physical Properties)

### -Dielectric Loss Tangent-

The dielectric loss tangent of the resin substrate is 0.020 or less, preferably 0.00050 to 0.020 and more preferably 0.00010 to 0.010.

### -Relative Permittivity-

A relative permittivity of the resin substrate is preferably 10 or more, more preferably 10 to 1,000, and still more preferably 30 to 100. In a case where the relative permittivity is 10 or more, an effect of shielding electromagnetic wave is increased, and thus function as a filter is increased. In addition, in the metamaterial layer including the specific conductor pattern, in a case where the relative permittivity is 10 or more, the pattern structure can be reduced, so that the metamaterial can be reduced in size and integrated.

### <Metamaterial Layer>

The metamaterial layer is disposed on at least one surface of the resin substrate.

The metamaterial layer includes a conductor pattern formed of at least one selected from the group consisting of a conductive material and a material which changes from an insulator to a conductor. The metamaterial layer may be disposed on both the at least one surface and the other surface of the resin substrate.

The conductive material is a material having conductivity. The conductivity means a property of a volume resistivity of less than 10⁸ Ωcm.

The conductive material preferably contains a metal, and more preferably is one or more selected from the group consisting of gold, silver, platinum, copper, and aluminum. Among these, from the viewpoint of area resistivity, the conductive material is particularly preferably at least one of gold or copper, and most preferably copper.

Examples of the material which changes from an insulator to a conductor include a material which changes from an insulator to a conductor by heating, light irradiation, or application of a voltage.

The material which changes from an insulator to a conductor is preferably at least one selected from the group consisting of a phase change material, a semiconductor, a conductive oxide, and a carbon material.

In the present disclosure, the phase change material means a material which causes a phase change between an amorphous phase and a crystalline phase by Joule heat due to an electric pulse.

Examples of the phase change material include vanadium oxide, an antimony tellurium (SbTe) alloy, a germanium tellurium (GeTe) alloy, a germanium antimony tellurium (GeSbTe) alloy, an indium antimony tellurium (InSbTe) alloy, and a silver indium antimony tellurium (AgInSbTe) alloy. Among these, from the viewpoint of easily controlling a temperature and a voltage at which the insulator is transited to the conductor, smoothness of the pattern, adhesiveness with the substrate, and the like, vanadium oxide or a GeSbTe alloy is preferable.

Examples of the semiconductor include a p-type n-conjugated polymer, a condensed polycyclic compound, a triarylamine compound, a hetero 5-membered ring compound, a phthalocyanine compound, and a porphyrin compound.

Examples of the conductive oxide include indium tin oxide (ITO), indium zinc oxide (IZO), zinc oxide (ZnO), and indium gallium zinc oxide (IGZO).

Examples of the carbon material include carbon nanotubes and graphene.

The conductor pattern may include a plurality of structural bodies. The conductor pattern may include two or more structural bodies having different shapes, sizes, and the like.

A shape of the structural body is not particularly limited, but is preferably a shape capable of inducing a dielectric or magnetic response change by generating a charge bias, a current, or the like in the structural body or between adjacent structural bodies due to an interaction between the electric field, the magnetic field, or the like of an electromagnetic wave in a terahertz band, which is incident on the metamaterial.

The shape of the structural body is not particularly limited, and examples thereof include a C-shape, a U-shape, a double ring shape, a V-shape, an L-shape, a lattice shape, a spiral shape, a square shape, a circular shape, and a cross shape in an in-plane direction of the resin substrate.

The structural body is composed of the conductive material or the material which transits from an insulator to a conductor.

From the viewpoint of reducing polarization dependence, the structural body preferably has a shape which is symmetric with respect to an X direction and a Y direction orthogonal to the X direction in the in-plane direction of the resin substrate; and examples thereof include a cross shape, a Jerusalem cross shape, a circular shape, and a square shape.

A size of the structural body is not particularly limited, and the maximum length of the structural body is preferably equal to or less than a wavelength size of the incident electromagnetic waves, more preferably 0.5 mm to 20 mm, and still more preferably 1 mm to 10 mm.

In the present disclosure, the maximum length of the structural body means a length which is longest in a case where a straight line is drawn from one end to the other end of the structural body in the in-plane direction of the substrate.

From the viewpoint of smoothness of the conductor pattern, a width of the structural body is preferably 3 μm to 400 μm. For example, in a case where the structural body has a C-shape, the width of the structural body refers to a length in a direction orthogonal to a longitudinal direction of the C-shape.

In addition, it is preferable that the shortest distance between the structural bodies is appropriately changed according to the shape, size, and the like of the structural body, and for example, it can be set to 20 μm to 1,000 μm.

In addition, in a case where the structural body is a split-ring resonator, from the viewpoint of smoothness of the conductor pattern, a gap is preferably 1 μm to 15 μm.

The split-ring resonator means a structural body having a C-shape or a U-shape.

A disposition position of the structural body on the surface of the resin substrate is not particularly limited, and is preferably a disposition in which the structural body resonates with the electromagnetic wave in the terahertz band.

In addition, the structural body may be disposed on the surface of the resin substrate, in which a periodic structure is formed such that the amount of phase shift of the electromagnetic wave in the terahertz band is continuously increased or decreased as the region moves from the center of the surface of the resin substrate to the outer side. Examples of the above-described periodic structure include a structure in which structural bodies having different diameters are arranged in a concentric circle. A change width of the diameter of the structural bodies arranged in a concentric circle can be set to 10 μm to 200 μm.

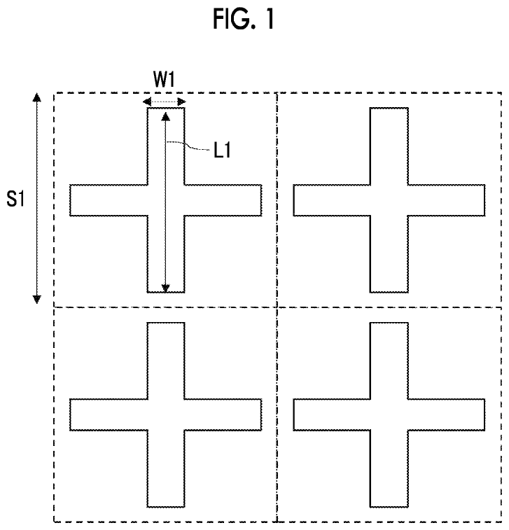

In a case where the shape of the structural body is a cross shape, for example, a shape in which a cross shape shown in FIG. 1 is used as a repeated unit can also be used. In FIG. 1, a pattern size Si is preferably 1 to 100 mm from the viewpoint of wavelength selectivity and transmission loss; a cross length L1 is preferably 1 to 50 mm from the viewpoint of wavelength selectivity and transmission loss; and a cross width W1 is preferably 0.1 to 20 mm from the viewpoint of wavelength selectivity and transmission loss.

From the viewpoint of electromagnetic wave transmittance, the conductor pattern preferably has an area resistivity of 1Ω/□ or less, more preferably has an area resistivity of 0.8Ω/□ or less, and still more preferably has an area resistivity of 0.01 Ω/□ to 0.6 Ω/□. In a case where the area resistivity is 1Ω/□ or less, a component which is lost as heat is reduced, so that a band-pass filter having a reduced insertion loss can be produced.

In the present disclosure, the area resistivity is measured using a resistance measuring device. As the resistance measuring device, a noncontact eddy current type resistance measuring device EC-80P manufactured by NAPSON or a device of the same level can be used.

From the viewpoint of electromagnetic wave transmittance, cost reduction, and the like, a thickness of the conductor pattern is preferably less than 5 μm, more preferably 0.01 μm to 4 μm, still more preferably 0.05 μm to 3 μm, and particularly preferably 0.1 μm to 1 μm.

In addition, in the present disclosure, the thickness of the conductor pattern is determined from an average value of any five points by measuring a cross section of the metamaterial layer in a thickness direction with a scanning electron microscope (SEM).

A method of forming the conductor pattern is not particularly limited, and for example, the pattern can be formed by forming a sputtered film on the surface of the substrate by a sputtering method, forming a resist pattern on a surface of the sputtered film, etching and removing the sputtered film not covered with the resist pattern, and then removing the resist pattern.

The method of forming the pattern is not limited to the above-described methods, and the vapor-deposited film may be formed by a vapor deposition method instead of the sputtering method.

### [Band-Pass Filter]

The band-pass filter according to the present disclosure preferably includes the above-described film or the above-described laminate.

The band-pass filter according to the present disclosure has a high-frequency band pass characteristic of transmitting only a specific frequency and not transmitting other frequencies in a frequency range of 1 GHz to 100 GHz.

A center frequency of the transmission band is suitable for 6 GHz to 24 GHz.

An insertion loss at the center frequency of the transmission band is preferably 0.5 dB or less, and more preferably 0.1 dB or less. The lower limit value of the above-described insertion loss is, for example, 0 dB.

An insertion loss at the center frequency of the transmission band 5 GHz is preferably 5 dB or more, and more preferably 8 dB or more. The upper limit value of the above-described insertion loss is, for example, 20 dB.

The band-pass filter according to the present disclosure is preferably used by being attached to an outside of an antenna. In the band-pass filter in the related art, the band-pass filter is installed in an antenna circuit, but the band-pass filter according to the present disclosure can be installed independently of the antenna circuit. This eliminates the need to install the band-pass filter in the antenna circuit.

### [Communication Terminal]

The communication terminal according to the present disclosure includes a communication circuit, an antenna, and the above-described band-pass filter which is disposed on an outside of the antenna.

Since the band-pass filter is attached to the outside of the antenna, a signal can be transmitted to the antenna by transmitting only a specific frequency and not transmitting other frequencies from received radio waves.

### EXAMPLES

Hereinafter, the present disclosure will be described in more detail with reference to Examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

Details of each material used for producing the film are as follows.

### <Inorganic Filler>

F1: pulverized product of barium titanate particles (average particle diameter: 2 μm, relative permittivity: 1,000, dielectric loss tangent: 0.015)
F2: pulverized product of barium titanate particles (average particle diameter: 0.18 μm, relative permittivity: 200, dielectric loss tangent: 0.30)
F3: pulverized product of titanium dioxide particles (average particle diameter: 7 μm, relative permittivity: 85, dielectric loss tangent: 0.013)
F4: pulverized product of strontium titanate particles (average particle diameter: 1 μm, relative permittivity: 300, dielectric loss tangent: 0.0050)

### <Resin>

P1: aromatic polyester amide produced by the following production method
P2: (meth)acrylic resin (product name “ACRYPET VRL20A”, manufactured by Mitsubishi Chemical Corporation, Tg=109 °C)

### -Synthesis of Aromatic Polyester Amide P1-

940.9 g (5.0 mol) of 6-hydroxy-2-naphthoic acid, 415.3 g (2.5 mol) of isophthalic acid, 377.9 g (2.5 mol) of acetaminophen, and 867.8 g (8.4 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23 °C; the same applies hereinafter) to 140 °C over 60 minutes while being stirred in a nitrogen gas stream and was refluxed at 140 °C for 3 hours.

Next, the temperature was raised from 150 °C to 300 °C over 5 hours while distilling off by-produced acetic acid and unreacted acetic acid anhydride, and maintained at 300 °C for 30 minutes. Thereafter, the content was taken out from the reactor and was cooled to room temperature. The obtained solid was pulverized by a pulverizer to obtain a powdered aromatic polyester amide P1a. A flow start temperature of the aromatic polyester amide P1a was 193 °C. In addition, the aromatic polyester amide P1a was a wholly aromatic polyester amide.

The aromatic polyester amide P1a was subjected to solid polymerization by increasing the temperature from room temperature to 160 °C over 2 hours and 20 minutes in a nitrogen atmosphere, increasing the temperature from 160 °C to 180 °C over 3 hours and 20 minutes, and maintaining the temperature at 180 °C for 5 hours, and then the resultant was cooled. Next, the resultant was pulverized by a pulverizer to obtain a powdered aromatic polyester amide P1b. A flow start temperature of the aromatic polyester amide P1b was 220 °C.

The aromatic polyester amide P1b was subjected to solid polymerization by increasing the temperature from room temperature to 180 °C over 1 hour and 25 minutes in a nitrogen atmosphere, increasing the temperature from 180 °C to 255 °C over 6 hours and 40 minutes, and maintaining the temperature at 255 °C for 5 hours, and then the resultant was cooled, thereby obtaining a powdered aromatic polyester amide P1.

A flow start temperature of the aromatic polyester amide P1 was 302 °C. In addition, in a case where a melting point of the aromatic polyester amide P1 was measured using a differential scanning calorimetry device, the measured value was 311 °C. A dielectric loss tangent of the aromatic polyester amide P1 was 0.0030.

### <Copper Foil>

M1: product name “CF-T49A-DS-18”, manufactured by Fukuda Metal Foil & Powder Co., Ltd., average thickness: 18 μm

### [Production of Single-Sided Copper-Clad Laminate]

### Examples 1 to 6, Examples 101 to 105, Comparative Examples 1 to 3, and Comparative Example 101

The inorganic filler and the resin shown in Tables 1 and 2 were mixed at contents (% by volume) shown in Tables 1 and 2, and dispersed with a beads mill to obtain a solution (dispersion liquid).

The obtained solution was fed to a slot die, and the solution was applied onto the copper foil M1 by adjusting a flow rate such that an average thickness after drying was the thickness shown in Tables 1 and 2. The solvent was removed from the coating film by hot air drying. Furthermore, the heat treatment was carried out by heating from 50 °C to 300 °C at a rate of 1 °C/min and holding at 300 °C for 2 hours in a nitrogen atmosphere to produce a single-sided copper-clad laminate.

### Comparative Example 102

The resin P2 was vacuum-dried at 100 °C, supplied to a single-axis extruder in which the inside of the raw material hopper to the extruder was replaced with nitrogen, melted at a cylinder set temperature of 230 °C to 270 °C, passed through a coating hanger-type T-die, and cooled by a chromium-plated casting roll at 120 °C and a chromium-plated cooling casting roll at 90 °C to produce a film.

The copper foil M1 and the film were laminated using a laminator (product name “Vacuum laminator V-130”, manufactured by Nikko-Materials Co., Ltd.) under conditions of 140 °C and a laminating pressure of 0.4 MPa for 1 minute to obtain a precursor of a single-sided copper-clad laminate. Furthermore, the precursor of the single-sided copper-clad laminate was subjected to a thermocompression bonding using a thermocompression bonding machine (product name “MP-SNL”, manufactured by Toyo Seiki Seisaku-sho, Ltd.) under conditions of 320 °C and 4 MPa to produce a single-sided copper-clad laminate.

### [Production of Double-Sided Copper-Clad Laminate]

### Example 106

The inorganic filler and the resin shown in Table 2 were mixed at contents (% by volume) shown in Table 2, and dispersed with a beads mill to obtain a solution (dispersion liquid).

The obtained solution was fed to a slot die, and the solution was applied onto the copper foil M1 by adjusting a flow rate such that an average thickness after drying was the thickness shown in Table 2. The solvent was removed from the coating film by hot air drying. Furthermore, the heat treatment was carried out by heating from 50 °C to 300 °C at a rate of 1 °C/min and holding at 300 °C for 2 hours in a nitrogen atmosphere to produce a single-sided copper-clad laminate.

The obtained single-sided copper-clad laminate and the copper foil M1 were laminated using a laminator (product name “Vacuum laminator V-130”, manufactured by Nikko-Materials Co., Ltd.)under conditions of 140 °C and a laminating pressure of 0.4 MPa for 1 minute to obtain a precursor of a double-sided copper-clad laminate. Furthermore, the obtained precursor of the double-sided copper-clad laminate was subjected to thermocompression bonding using a thermocompression bonding machine (product name “MP-SNL”, manufactured by Toyo Seiki Seisaku-sho, Ltd.) under conditions of 320 °C and 4 MPa to produce a double-sided copper-clad laminate.

### [Formation of Conductor Pattern]

For the obtained single-sided copper-clad laminate of Examples 101 to 105 and Comparative Example 102, and the obtained double-sided copper-clad laminate of Example 106, the copper foil was etched by a known method to form a pattern in which the cross shape shown in FIG. 1 was used as a repeated unit. The formed conductor pattern was a metamaterial which selectively transmitted in a vicinity of 10 GHz.

### [Production of Communication Terminal Having Band-Pass Filter]

Using the single-sided copper-clad laminate or the double-sided copper-clad laminate produced above as a laminate, the laminate was bonded to a patch antenna of a smartphone through a gluing agent to produce a communication terminal having a band-pass filter.

### <<Evaluation>>

The following measurements and evaluations were performed, and the results are shown in Tables 1 and 2.

### [Relative Permittivity and Dielectric Loss Tangent]

The film obtained by removing the copper foil of the single-sided copper-clad laminate and the double-sided copper-clad laminate with an aqueous solution of ferric chloride, washing with pure water, and drying was used for measurement.

A relative permittivity and a dielectric loss tangent were measured by a resonant perturbation method at a frequency of 10 GHz. A 10 GHz cavity resonator (“CP531” manufactured by Kanto Electronic Application & Development Inc.) was connected to a network analyzer (“E8363B” manufactured by Agilent Technology Company), the film was inserted into the cavity resonator, and the measurement was performed from the change in resonance frequency before and after the insertion for 96 hours in an environment of a temperature of 25 °C and a humidity of 60% RH, thereby measuring the relative permittivity and the dielectric loss tangent of the film.

### [Insertion Loss]

A receiving horn antenna was connected to a Port 1 of a network analyzer (“E8363B” manufactured by Agilent Technology Company), and a transmitting horn antenna was connected to a Port 2. The receiving horn antenna and the transmitting horn antenna were disposed such that the receiving horn antenna and the transmitting horn antenna faced each other.

A steel sheet was bonded to a radio wave absorber having an opening portion to produce a sample holding member. Both ends of a measurement sample were inserted into opening portions of the two sample holding members.

The measurement sample held by the sample holding member was disposed between the receiving horn antenna and the transmitting horn antenna such that radio waves could be transmitted through the measurement sample.

The radio waves were transmitted and received, and an S parameter S21 was measured. An attenuation amount (insertion loss) of the radio waves in a case where the measurement sample was installed was measured using the transmittance in a case where the measurement sample was not installed as a reference.

In Table 1, the left side of Expression (A) indicates “λ/(2×√ε)−λ/50”, and the right side of Expression (A) indicates “λ/(2×√ε)+λ/50”. λ represents the central wavelength of transmission, and ε represents the relative permittivity.

In Tables 1 and 2, the center frequency of transmission means a center frequency in the transmission band.

TABLE 1

| | | Exam- | Exam- | Exam- | Exam- | Exam- | Exam- | Comparative | Comparative | Comparative |
|---|---|---|---|---|---|---|---|---|---|---|
| | | ple 1 | ple 2 | ple 3 | ple 4 | ple 5 | ple 6 | Example 1 | Example 2 | Example 3 |
| Resin | | P1 | P1 | P1 | P1 | P1 | P1 | P1 | P1 | P1 |
| Inorganic | Type | F1 | F1 | F3 | F3 | F4 | F4 | — | F1 | F2 |
| filler | Formulation | BaTiO₃ | BaTiO₃ | TiO₂ | TiO₂ | SrTiO₃ | SrTiO₃ | — | BaTiO₃ | BaTiO₃ |
| | Particle | 2.0 | 2.0 | 7.0 | 7.0 | 1.0 | 1.0 | — | 2.0 | 0.18 |
| | diameter | | | | | | | | | |
| | [μm] | | | | | | | | | |
| | Content [% | 36 | 75 | 40 | 86 | 39 | 83 | — | 36 | 40 |
| | by volume] | | | | | | | | | |
| Relative permittivity | | 10 | 38 | 10 | 38 | 10 | 38 | 3.8 | 10 | 11 |
| Dielectric loss tangent | | 0.0050 | 0.0050 | 0.0047 | 0.0034 | 0.0020 | 0.0010 | 0.0050 | 0.0050 | 0.021 |
| Thickness [mm] | | 4.74 | 2.43 | 4.74 | 2.43 | 4.74 | 2.43 | 7.69 | 1.00 | 4.52 |
| Center frequency | | 10 | 10 | 10 | 10 | 10 | 10 | 10 | 10 | 10 |
| of transmission | | | | | | | | | | |
| [GHz] | | | | | | | | | | |
| Central wavelength | | 30.0 | 30.0 | 30.0 | 30.0 | 30.0 | 30.0 | 30.0 | 30.0 | 30.0 |
| of transmission | | | | | | | | | | |
| [mm] | | | | | | | | | | |
| Left side of | | 5.34 | 3.03 | 5.34 | 3.03 | 5.34 | 3.03 | 8.29 | 5.34 | 5.12 |
| Expression (A) | | | | | | | | | | |
| [mm] | | | | | | | | | | |
| Right side of | | 4.14 | 1.83 | 4.14 | 1.83 | 4.14 | 1.83 | 7.09 | 4.14 | 3.92 |
| Expression (A) | | | | | | | | | | |
| [mm] | | | | | | | | | | |
| Insertion | 10 GHz | 0.05 | 0.6 | 0.05 | 0.09 | 0.05 | 0.03 | 0.03 | 0.01 | 0.03 |
| loss | 5 GHz | 4.8 | 10 | 4.8 | 10 | 4.8 | 10 | 1.8 | 0.01 | 1.8 |
| [dB] | 15 GHz | 4.8 | 10 | 4.8 | 10 | 4.8 | 10 | 1.8 | 0.01 | 1.8 |

TABLE 2

| | | | Exam- | Exam- | Exam- | Exam- | Exam- | Exam- | Comparative | Comparative |
|---|---|---|---|---|---|---|---|---|---|---|
| | | | ple 101 | ple 102 | ple 103 | ple 104 | ple 105 | ple 106 | Example 101 | Example 102 |
| Resin | Resin | | P1 | P1 | P1 | P1 | P1 | P1 | P1 | P2 |
| substrate | Inorganic | Type | — | — | — | F1 | F3 | F3 | — | — |
| | filler | Formulation | — | — | — | BaTiO₃ | TiO₂ | TiO₂ | — | — |
| | | Particle | — | — | — | 2.0 | 7.0 | 7.0 | — | — |
| | | diameter | | | | | | | | |
| | | [μm] | | | | | | | | |
| | | Content [% | — | — | — | 36 | 86 | 86 | — | — |
| | | by volume] | | | | | | | | |

| | Relative permittivity | 3.8 | 3.8 | 3.8 | 10 | 38 | 38 | 3.8 | 4.3 |
|---|---|---|---|---|---|---|---|---|---|
| | Dielectric loss tangent | 0.0020 | 0.0020 | 0.0020 | 0.0030 | 0.0030 | 0.0030 | 0.0020 | 0.025 |
| | Thickness [mm] | 0.5 | 0.5 | 0.5 | 0.5 | 0.5 | 0.025 | 0.5 | 0.5 |
| Conductor | Area resistivity | 5 | 1 | 0.001 | 0.001 | 0.001 | 0.001 | — | 5 |
| pattern | [Ω/□] | | | | | | | | |
| | Size [mm□] | 15 | 15 | 15 | 10 | 5 | 5 | — | 15 |
| | Forming surface of | Single- | Single- | Single- | Single- | Single- | Double- | — | Single- |
| | conductive pattern | sided | sided | sided | sided | sided | sided | | sided |
| Center frequency | | 10 | 10 | 10 | 10 | 10 | 10 | 10 | 10 |
| of transmission | | | | | | | | | |
| [GHz] | | | | | | | | | |
| Insertion | 10 GHz | 0.8 | 0.5 | 0.1 | 0.1 | 0.8 | 0.1 | 0.03 | 1.0 |
| loss | 5 GHz | 15 | 15 | 15 | 15 | 15 | 15 | 1.8 | 15 |
| [dB] | 15 GHz | 15 | 15 | 15 | 15 | 15 | 15 | 1.8 | 15 |

As shown in Table 1, in Examples 1 to 6, since the film contained the inorganic tiller and the resin, the thickness d satisfied the expression (A), the relative permittivity was 10 or more, and the dielectric loss tangent was 0.020 or less, the insertion loss at the center frequency of transmission of 10 GHz could be suppressed.

On the other hand, in Comparative Example 1, since the inorganic filler was not contained, the frequency other than the center frequency of transmission of 10 GHz was also transmitted.

In Comparative Example 2, since the thickness d did not satisfy the expression (A), the frequency other than the center frequency of transmission of 10 GHz was also transmitted.

In Comparative Example 3, since the dielectric loss tangent was more than 0.020, the frequency other than the center frequency of transmission of 10 GHz was also transmitted.

As shown in Table 2, in Examples 101 to 106, since the laminate included the resin substrate having a dielectric loss tangent of 0.020 or less and the metamaterial layer including the conductor pattern disposed on at least one surface of the resin substrate, the insertion loss at the center frequency of transmission of 10 GHz could be suppressed.

On the other hand, in Comparative Example 101, since the conductor pattern was not formed, the frequency other than the center frequency of transmission of 10 GHz was also transmitted.

In Comparative Example 102, since the dielectric loss tangent was more than 0.020, the insertion loss at the center frequency of transmission of 10 GHz could not be suppressed.

In Example 102, since the area resistivity of the conductor pattern was 1Ω/□ or less, the insertion loss at the center frequency of transmission of 10 GHz could be further suppressed as compared with Example 101.

The disclosure of Japanese Patent Application No. 2023-150290 filed on Sep. 15, 2023 is incorporated in the present specification by reference. In addition, all documents, patent applications, and technical standards described in the present specification are incorporated herein by reference to the same extent as in a case of being specifically and individually noted that individual documents, patent applications, and technical standards are incorporated by reference.

What is claimed is:

1. A film comprising:
an inorganic filler; and
a resin,
wherein a thickness d satisfies the following expression (A), and
a relative permittivity is 10 or more and a dielectric loss tangent is 0.020 or less,
λ/(2×√ε)−λ/50≤d≤λ/(2×√ε)+λ/50 Expression (A),
in the expression (A), d represents a thickness in units of mm, λ represents a central wavelength of transmission which is expressed as 100c/f in units of mm, c represents a propagation speed of an electromagnetic wave in units of m/s, f represents a center frequency of transmission in units of GHz, and ε represents a relative permittivity.

2. The film according to claim 1,
wherein the inorganic filler has a relative permittivity of 6 to 20,000.

3. The film according to claim 1,
wherein the inorganic filler includes at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.

4. The film according to claim 1,
wherein the inorganic filler has an average particle diameter of 0.01 μm to 10 μm.

5. The film according to claim 1,
wherein a content of the inorganic filler is 1% by volume to 90% by volume with respect to a total amount of the film.

6. The film according to claim 1,
wherein the resin includes at least one selected from the group consisting of a thermoplastic resin, a thermoplastic elastomer, a semicured product of a thermosetting resin, a cured product of a thermosetting resin, a semicured product of a thermosetting elastomer, and a cured product of a thermosetting elastomer.

7. The film according to claim 1,
wherein the thickness is 0.1 mm to 8 mm.

8. A laminate comprising:
a resin substrate having a dielectric loss tangent of 0.020 or less; and
a metamaterial layer including a conductor pattern formed of at least one selected from the group consisting of a conductive material and a material which changes from an insulator to a conductor, the conductor pattern being disposed on at least one surface of the resin substrate.

9. The laminate according to claim 8,
wherein the resin substrate has a relative permittivity of 10 or more.

10. The laminate according to claim 8,
wherein the resin substrate contains an inorganic filler and a resin.

11. The laminate according to claim 10,
wherein the inorganic filler has a relative permittivity of 6 to 20,000.

12. The laminate according to claim 10,
wherein the inorganic filler includes at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.

13. The laminate according to claim 10,
wherein the inorganic filler has an average particle diameter of 0.01 μm to 10 μm.

14. The laminate according to claim 10,
wherein a content of the inorganic filler is 1% by volume to 90% by volume with respect to a total amount of the resin substrate.

15. The laminate according to claim 10,
wherein the resin includes at least one selected from the group consisting of a thermoplastic resin, a thermoplastic elastomer, a semicured product of a thermosetting resin, a cured product of a thermosetting resin, a semicured product of a thermosetting elastomer, and a cured product of a thermosetting elastomer.

16. The laminate according to claim 8,
wherein the conductor pattern has an area resistivity of 1Ω/□ or less.

17. A band-pass filter comprising:
the film according to claim 1 or the laminate according to claim 8.

18. The band-pass filter according to claim 17,
wherein a center frequency of a transmission band is 6 GHz to 24 GHz.

19. The band-pass filter according to claim 17,
wherein an insertion loss at a center frequency of a transmission band ±5 GHz is 5 dB or more.

20. The band-pass filter according to claim 17,
wherein the band-pass filter is used by being attached to an outside of an antenna.

21. A communication terminal comprising:
a communication circuit;
an antenna; and
the band-pass filter according to claim 17, which is disposed on an outside of the antenna.
